(19) United States
(12) Patent Application Publication
(10) Pub. No.: US 2026/0055496 A1
(43) Pub. Date: Feb. 26, 2026

(54) SUBSTRATE COATING FOR HIGH VOLTAGE APPLICATIONS

(71) Applicant: NxEdge, Inc., Boise, ID (US)

(72) Inventors: Jesse Armagost, Boise, ID (US); Kiev Dixon, Boise, ID (US)

(21) Appl. No.: 19/304,263

(22) Filed: Aug. 19, 2025

Related U.S. Application Data
(60) Provisional application No. 63/685,108, filed on Aug. 20, 2024.

(51) Int. Cl. C23C 4/134; C23C 4/06; C23C 4/11; H01L 21/683

(52) U.S. Cl. CPC C23C 4/134; C23C 4/06; C23C 4/11; H01L 21/6833

(57) ABSTRACT

A substrate configured to withstand a high electrical voltage. The substrate comprises a functional electrical layer formed on the substrate using either atmospheric plasma spray (APS) suspension plasma spray (SPS). A high strength dielectric material is coated onto the functional electrical layer using SPS. A clamping layer is coated on the high strength dielectric material using either APS or SPS.

### CROSS-REFERENCE TO RELATED PATENT APPLICATIONS

This application claims the benefit of U.S. Provisional Ser. No. 63/685,108 filed Aug. 20, 2024, the entire contents of which is incorporated by reference herein.

### BACKGROUND

Substrates in the semiconductor field are often subject to high voltage applications. The substrates may use a dielectric material in these high voltage applications, but such dielectrics are subject to high voltage breakdown.

Dielectric high voltage breakdown, a/k/a electrical breakdown, occurs when the dielectric material, or other insulating material, is subjected to a high enough electric field that it becomes conductive, allowing current to flow, i.e., break, through it. This breakdown may happen because the electric field intensity exceeds the dielectric strength of the material, causing the dielectric material to fail. When this occurs, electrons within the material gain enough energy to free other electrons from their atomic bonds, creating a cascade effect that results in a sudden surge of current. This process can cause significant damage to material and is a critical consideration in the design of electrical and electronic systems.

The dielectric breakdown strength of a material is an important parameter and varies depending on several factors, including the type of material, the amount of material (in general, its thickness and density), its temperature, the presence of impurities, and the frequency of the applied electric field. For instance, solid dielectrics like ceramics or glass generally have higher breakdown strengths compared to gases or liquids. However, even the best insulators can fail if the applied voltage is high enough. Engineers must carefully select materials and design systems to ensure that the operating voltages stay well below the breakdown thresholds to maintain reliability and safety

There are different modes of dielectric breakdown, including thermal breakdown, avalanche breakdown, and partial or localized discharge (or breakdown), although all lead to flow across the material. Thermal breakdown occurs when the heat generated by the electric field causes the material to degrade and lose its insulating properties. Avalanche breakdown involves the ionization of atoms within the dielectric material, leading to a rapid increase in free electrons and current (the aforementioned cascade effect). Partial or localized discharge is a localized form of dielectric breakdown that can occur in regions of high electric stress within the material, eventually leading to complete failure if not managed properly. Understanding these modes helps in diagnosing failures and improving the design of insulating systems.

Preventing dielectric breakdown is crucial in any high voltage application, such as power transmission, semiconductor manufacturing, capacitors, and electronic components. Engineers use various techniques to enhance the dielectric strength of materials and manage electric fields. This includes using composite materials with higher breakdown strengths, applying protective coatings, and designing geometric configurations that minimize high electric field regions. Proper maintenance and regular testing are also essential to ensure that insulating materials retain their properties over time. By addressing these factors, the risk of dielectric high voltage breakdown can be significantly reduced, ensuring the reliability and longevity of electrical systems.

One exemplary substate that is often coated with a dielectric material is an electrostatic chuck (“echuck” or “ESC”). ESCs are used extensively in semiconductor manufacturing and other precision applications to hold wafers or other substrates in place using electrostatic forces. The risk of dielectric breakdown in ESCs is a critical concern because it can lead to significant operational failures and costly downtime. Dielectric breakdown in an ESC can cause a sudden loss of its ability to securely hold the wafer, or work piece, potentially leading to damage to the work piece and the chuck itself. This breakdown can also introduce contaminants and particles, compromising the cleanliness required in semiconductor manufacturing processes.

One major risk factor for dielectric breakdown in electrostatic chucks is the high voltage used to generate the electrostatic forces that clamp the work piece to the ESC. The materials used in the chuck must have sufficient dielectric strength to withstand these voltages without breaking down. Any weaknesses or defects in the dielectric material, such as impurities, voids, or cracks, can become focal points for dielectric breakdown. These defects can be introduced during the manufacturing process or develop over time due to thermal cycling and mechanical stress.

Another risk factor is the operating environment of the ESC. High temperatures, which are common in semiconductor manufacturing processes, can reduce the dielectric strength of the materials used in the chuck. Additionally, the presence of reactive chemicals or gases (generically a hostile environment) can degrade the dielectric material, increasing the likelihood of breakdown. Continuous exposure to high electric fields can also lead to gradual deterioration of the dielectric properties, making breakdown more likely over time.

Thus, against this background, it would be desirable to provide an improved substate coating for high voltage applications.

### SUMMARY

This Summary is provided to introduce a selection of concepts in a simplified form that are further described below in the Detailed Description. This Summary, and the foregoing Background, is not intended to identify key aspects or essential aspects of the claimed subject matter. Moreover, this Summary is not intended for use as an aid in determining the scope of the claimed subject matter.

The technology of the present application provides a coated substrate, such as an electrostatic chuck, for high voltage applications. The coated substrate is formed by coating a handle, or base plate. The handle is first coated with a first material to form a pedestal, which may be a cooling base, where the first material is often a dielectric material. The first material may be coated on the handle using atmospheric plasma spray or suspension plasma spray processes to form the cooling base, wherein the cooling base may comprise a plurality of layers. A metal portion if formed on the cooling base in a conventional manner. The metal portion includes electrodes configured to be coupled to a power source. The cooling base with the metal portion is next coated with a high strength dielectric material using suspension plasma spray to form the high strength dielectric portion. Finally, the high strength dielectric portion receives a clamping (or top) layer that is coated on the high strength dielectric portion. The top surface, or clamping surface, for an electrostatic chuck may be formed with a pattern, textured, or the like. The top surface is formed using a clamp surface dielectric material, different from the high strength dielectric material and may comprise aluminum oxide. The top surface, or clamping surface, is formed using atmospheric plasma spray although suspension plasma spray could be used. The top surface dielectric material may be formed from a plurality of layers.

These and other aspects of the present system and method will be apparent after consideration of the Detailed Description and Figures herein.

### BRIEF DESCRIPTION OF THE DRAWINGS

Non-limiting and non-exhaustive embodiments of the present invention, including the preferred embodiment, are described with reference to the following figures, wherein like reference numerals refer to like parts throughout the various views unless otherwise specified.

FIG. 1 depicts a cross-sectional view of a coated substrate consistent with the technology of the present application.

FIG. 2 depicts an illustrative flow diagram for a method of forming the coated substate of FIG. 1 consistent with the technology of the present application.

### DETAILED DESCRIPTION

Embodiments are described more fully below with reference to the accompanying figures, which form a part hereof and show, by way of illustration, specific exemplary embodiments. These embodiments are disclosed in sufficient detail to enable those skilled in the art to practice the invention. However, embodiments may be implemented in many different forms and should not be construed as being limited to the embodiments set forth herein. The following detailed description is, therefore, not to be taken in a limiting sense. Moreover, the technology of the present application will be described with relation to exemplary embodiments. The word “exemplary” is used herein to mean “serving as an example, instance, or illustration.” Any embodiment described herein as “exemplary” is not necessarily to be construed as preferred or advantageous over other embodiments. Additionally, unless specifically identified otherwise, all embodiments described herein should be considered exemplary.

The technology of the present application is generally described with respect to coatings on electrostatic chucks (ESCs) and the like. ESCs are substrates designed to hold work pieces in process chambers. Electrostatic chucks are susceptible to voltage breakdown (also known as electrical breakdown) because the ESC's dielectric/insulating layers are subject to repetitive high voltage applications as well as high, and sometimes extreme, temperature environments. Although described with respect to ESCs, the technology of the present application may be applied to coat other substrates, filters, optics, or the like.

ESCs typically include a base plate, or handle. The handle often has a coating of material deposited on the handle. For example, the handle may include a coating that forms a pedestal or a cooling base. The coating on the ESC may be a number of dielectric materials such that the coating includes depositing successive dielectric portions on the handle, such as, for example, a first (1^{st}) dielectric portion, a second (2^{nd}) dielectric portion, etc. Other portions, such as metal portions, may be deposited between the successively coated dielectric portions.

Moreover, each portion may comprise several layers of a material deposited on the handle. For example, the cooling base may comprise several layers of the deposited first material. The other layers may include metal layers, as mentioned above. For example, ESCs also have at least one deposited metal portion interspersed between the cooling base and subsequent dielectric layers. The metal portion, sometimes referred to as a functional metal portion, may include metal to act as an electrode or the like. For an ESC, the electrodes may be operatively coupled to a power source or a voltage source. When the power source is on, and coupled to the electrodes, the electrodes provide the clamping force to hold the work piece to a clamping portion coated on the handle. The clamping force is generated by exposing the material between the electrodes and the work piece to a relatively high voltage. The ESC top layer conventionally has an embossed, or otherwise textured, surface to facilitate clamping and declamping of a work piece to the ESC.

The top layer (or top surface), in some instances, is referred to as a clamping portion, clamping layer, or clamping surface.

During operation, the work piece is placed on the clamping layer and held by the ESC via a clamping force provided by a chucking voltage. The technology of the present application allows ESCs to have a chucking voltage of at least 1000 VDC. In some instances, the technology of the present application allows ESCs to have a chucking voltage of at least 5000 VDC. In still other instances, the technology of the present application allows ESCs to have a chucking voltage between about 1000 VDC and 5000 VDC. A power source operationally coupled to the electrodes is energized to induce the chucking voltage in the ESC, via the metal layer, such that the work piece is fixed to the ESC. The work piece is exposed to a chamber environment, which is hostile and hot, while the clamping force is applied for a procedure. While dependent on the chamber conditions, a chamber may in some instances have a temperature of about 150° C. When the procedure is completed, the power source is de-energized and the chucking voltage dissipates allowing the work piece to be removed. A fluid may be supplied in the channels, or troughs, formed by the texture on the clamping layer to facilitate removal of the workpiece. The ESC would subsequently receive a new work piece and the process is repeated.

Higher clamping forces require higher chucking voltages. However, as can be appreciated, higher voltages may cause voltage breakdown of the dielectric material, either at the initial application or earlier than desired as the material wears or corrodes due to exposure to the chamber environment. Additionally, the repetitive application of the chucking voltage and the high temperatures of the process chambers involved tend to cause increased wear of the dielectric material that causes, even high resistance material, to wear and become susceptible to voltage breakdown.

The voltage breakdown for dielectric/insulating material used with substrates, such as ESCs, is constrained, in part, by material requirements and the allowable thickness or depth of the dielectric/insulating layer. For example, many conventional ESC specifications require the clamping layer of the ESC to be formed from aluminum oxide (Al₂O3). Al₂O3 has a particular voltage breakdown in these applications of about 500 V/mm. While not to be constrained by any theory, any given material for an application will have an ability to withstand higher voltages when the dielectric material layer is thicker, generally, more dielectric material means the voltage required to breakthrough the dielectric material increase. However, the ability to increase the thickness of the Al₂O3 layer is constrained in most applications, which has the effect of limiting the chucking force that can be applied through the ESC. For example, the thickness of the material is constrained because the clamping force decreases with the distance from the electrode layer. Thus, the thickness of the coating on an ESC above the electrodes is typically no more than about 500 microns.

The technology of the present application provides for a low profile ESCs with Al₂O3 as the clamping layer that can withstand voltages of greater than about 1000 v/mm, which is above the voltage breakdown of a traditional Al₂O₃ coating. The coating on the ESC in this instance has a thickness of up to about 3 microns.

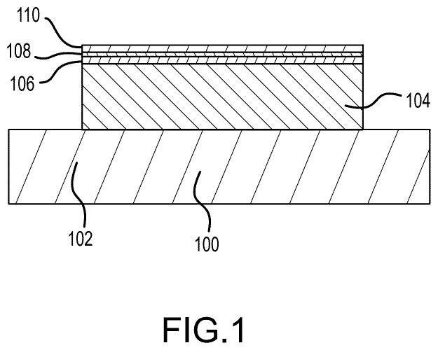

FIG. 1 shows an ESC 100 that comprises a handle 102, a cooling base 104, a functional portion 106, a high strength dielectric portion 108, and a clamping layer 110. The clamping layer 110 is shown having a smooth and planar top surface, but the top surface textured forming a textured clamping layer 110, such as embossed or the like. The ESC 100 may be formed with layers and material not otherwise presently shown, which omissions should not be considered limiting as the omissions are for clarity with respect to the technology of the present application. The different portions of the ESC 100 including the cooling base 104, the functional portion 106, the second dielectric portion 108, and the clamping layer 110 may be formed by a single layer or multiple layers of deposited material

The cooling base 104 is generally formed from a metallic material. To make the ESC 100, the cooling base 104 is deposited on the handle 102 using at least one of atmospheric plasma spray (APS) or suspension plasma spray (SPS), both of which are explained further below. The cooling base 104 may be a layer on which other material may be deposited.

SPS is a process carried out in a process chamber where a suspension containing particulate is used as feedstock to coat a substrate. The feedstock is provided in a reservoir. The suspension comprises a liquid carrier suspending particles in the liquid, also known as a resin or a slurry. The slurry is injected into a plasma plume from a plasma jet. The plasma jet evaporates the liquid carrier, melts the particles, and propels the particles to the substrate where it adheres to the substrate, either a top surface of the base plate or the previously deposited material.

APS, similar to SPS, is a process carried out in a process chamber. APS uses a feedstock of particulate to coat a substrate where the feedstock is injected into a plasma plume from a plasma jet using air, or other gas. The air, or other gas, dissipates, and the plasma jet melts and propels the particles to the substrate where they adhere to the surface.

To continue to build the ESC 100, after the cooling base 104 is deposited, which may comprise a plurality of layers deposited on the ESC 100, a metal portion 106 is formed on the cooling base 104. The metal portion 106, such as the aforementioned electrodes, includes metallic parts that are placed on the top surface of the cooling base 104. Gaps between the metallic parts are filled by a dielectric material, which could be considered part of cooling base, the high strength dielectric portion, or a separate layering of dielectric materials. The dielectric part of the metal portion may be formed from the same materials used for the cooling base 104 and deposited using APS or SPS. The dielectric portion of the metal portion 106 may use the same or different particles than the cooling base 104 or the high strength dielectric portion 108.

Once the metal portion 106 is formed on the cooling base 104, the ESC build is continued by placing the high strength dielectric portion 108 over the metal portion 106. The high strength dielectric portion 108 may be formed, in part, by the same material as the cooling base 104. The high strength dielectric portion 108 in one exemplary embodiment is Yttria. Other glass, ceramic, or combinations thereof may be used as the material to form the high strength dielectric potion 108. Such materials include other rare earth oxide material. In certain embodiments, the material used for the cooling base and the high strength dielectric portion may be the same. In other embodiments, the material used for the cooling base and the high strength dielectric portion may be different. The high strength dielectric portion 108 is formed using SPS. SPS is used in leu of APS, in part, because the deposited layers are generally more homogenous with porosity that is in the sub-micron scale. The high strength dielectric portion 108 is generally between about 100 and 200 microns in thickness, but may be more or less in certain embodiments depending on the chucking voltage to be applied.

After depositing the part of the high strength dielectric portion 108, the clamping layer 110 is deposited on the high strength dielectric portion 108. The clamping layer 110, as used here, is described separate from the high strength dielectric portion 108, but the clamping layer 110 may, in the alternative, be considered integral with the high strength dielectric portion 108. In any event, the clamping layer comprises aluminum oxide (Al₂O3) in one exemplary embodiment. The exemplary embodiment described herein is specific to Al₂O3 as this is often the desired material for the clamping surface 110 of the ESC 100. Other materials, such as, for example, rare earth oxides, fluorides, combinations thereof, or the like may be used instead of Al₂O3. The clamping layer 110 is generally between about 150 and 200 microns in thickness but could be more or less depending on the application, environment, and chucking voltage among other things.

The high strength dielectric portion 108 is formed by using SPS to layer dielectric particles on the previously deposited material, which in this example includes the cooling base 104 and the functional layer 106. The clamping layer 110, which may be textured, is formed by layering dielectric particles on the deposited high strength dielectric portion 108 using an atmospheric plasma spray (APS). The clamping layer 110 may be deposited using a suspension plasma spray (SPS), a combination of APS and SPS, or the like as well.

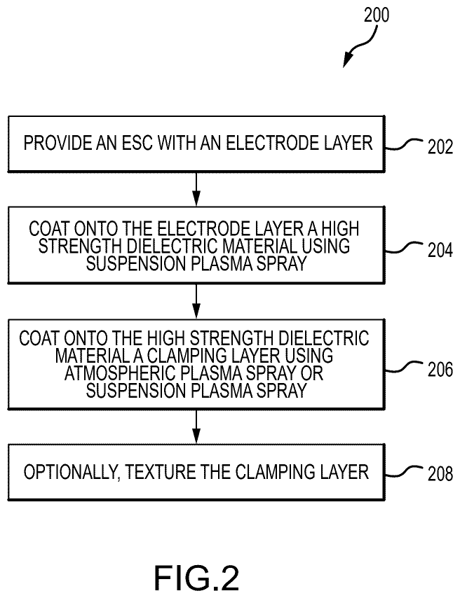

The substrate, such as an ESC, for use with in high voltage applications may be made in accordance with the steps of FIG. 2. First, at step 1, an ESC with an electrode layer is provide. The ESC, or substrate, with the electrode layer may include a cooling base, or other pedestal and a functional metallic layer. Second, at step 2, a coating of a high breakdown strength material, such as a ceramic like Yttrium, is coated on the functional metallic layer, sometime directly coated on the functional metallic layer, and sometimes there are other layers interspersed. Third, at step 3, a clamping layer is formed by coating aluminum oxide onto the high strength dielectric material. Lastly, and optionally, at step 4, the clamping layer may be textured.

Although the technology has been described in language that is specific to certain structures, materials, and methodological steps, it is to be understood that the invention defined in the appended claims is not necessarily limited to the specific structures, materials, and/or steps described. Rather, the specific aspects and steps are described as forms of implementing the claimed invention. Since many embodiments of the invention can be practiced without departing from the spirit and scope of the invention, the invention resides in the claims hereinafter appended. Unless otherwise indicated, all numbers or expressions, such as those expressing dimensions, physical characteristics, etc. used in the specification (other than the claims) are understood as modified in all instances by the term “approximately.” At the very least, and not as an attempt to limit the application of the doctrine of equivalents to the claims, each numerical parameter recited in the specification or claims which is modified by the term “approximately” should at least be construed in light of the number of recited significant digits and by applying ordinary rounding techniques. Moreover, all ranges disclosed herein are to be understood to encompass and provide support for claims that recite any and all subranges or any and all individual values subsumed therein. For example, a stated range of 1 to 10 should be considered to include and provide support for claims that recite any and all subranges or individual values that are between and/or inclusive of the minimum value of 1 and the maximum value of 10; that is, all subranges beginning with a minimum value of 1 or more and ending with a maximum value of 10 or less (e.g., 5.5 to 10, 2.34 to 3.56, and so forth) or any values from 1 to 10 (e.g., 3, 5.8, 9.9994, and so forth).

What is claimed is:

1. A substrate for using in high voltage applications comprising:
a substrate, the substrate configured to be coated using atmospheric plasma spray (APS), suspension plasma spray (SPS), or a combination thereof;
a functional metallic portion formed on substrate, wherein the functional metallic portion comprises electrodes configured to be operationally coupled to a power source such that a voltage is induced in the electrodes;
a high strength dielectric portion formed on the functional metallic portion such that the high strength dielectric portion comprises a plurality of layers of high strength dielectric material that covers the electrodes, wherein the high strength dielectric material is deposited using SPS and has a breakdown voltage of at least 1000 volts/mm;
a clamping layer formed on the high strength dielectric portion, the clamping layer is formed from a second material different than the high strength dielectric material.

2. The substrate of claim 1, wherein the clamping layer is textured.

3. The substrate of claim 1, comprising a pedestal formed onto the top surface of the substrate, wherein the pedestal is formed from a first material.

4. The substrate of claims 3, wherein pedestal is a cooling base.

5. The substrate of claim 1, wherein the high strength dielectric material is a ceramic material.

6. The substrate of claim 5, wherein the ceramic material is selected from a group of ceramic materials consisting of: Yttria, rare earth oxides, or a combination thereof.

7. The substrate of claim 6, wherein the clamping layer comprises a plurality of layers of aluminum oxide material deposited on high strength dielectric portion.

8. The substrate of claim 1, wherein the voltage induced in the electrodes is at least 1000 volts DC.

9. The substrate of claim 1, wherein the first material is different than the high strength dielectric material.

10. The substrate of claim 1, wherein the first material is the same as the high strength dielectric material.

11. The substrate of claim 1, wherein the first material is the same as the second material.

12. The substrate of claim 8, wherein the voltage induced in the electrodes is at least 5000 volts DC.

13. A method of making a high dielectric strength electrostatic chuck, comprising
provide a base wherein the base comprises a substrate configured to be coated using atmospheric plasma spray (APS) or suspension plasma spray (SPS);
forming, on the base, a functional metallic layer, wherein the functional metallic layer is configured to be electrically coupled to a power source to induce a voltage in the functional metallic layer, which voltage is configured to provide a clamping force;
coating, using SPS, a high strength dielectric material over at least the functional metallic layer formed on the base; and
coating, using either APS or SPS, a clamping layer on the high strength dielectric material, wherein the clamping layer is configured to hold and release a workpiece.

14. The method of claim 13, comprising texturing the clamping layer.

15. The method of claim 13, wherein coating the high strength dielectric material comprises coating a ceramic material over at least the functional metallic layer.

16. The method of claim 15, wherein coating the ceramic material comprises coating Yttria.

17. The method of claim 15 wherein coating the clamping layer comprises coating aluminum oxide.

18. An electrostatic chuck comprising:
a handle, the handle configured to be coated using atmospheric plasma spray (APS), suspension plasma spray (SPS), or a combination thereof;
a pedestal formed on the handle, the pedestal being formed using APS, SPS, or a combination thereof;
electrodes formed on pedestal, wherein the electrodes are configured to be operationally coupled to
a power source such that a voltage is induced in the electrodes;
a ceramic dielectric formed on the electrodes and pedestal such that the ceramic dielectric comprises a plurality of layers of a ceramic material, wherein the ceramic dielectric is deposited using SPS and has a breakdown voltage of at least 1000 volts/mm; and
a clamping layer formed on the ceramic dielectric, the clamping layer is formed from aluminum oxide.

19. The electrostatic chuck of claim 18, wherein the ceramic material is Yttria.

20. The electrostatic chuck of claim 18, wherein the pedestal is formed from a pedestal material different from the ceramic material.
